(19) United States
(12) Patent Application Publication
(10) Pub. No.: US 2025/0092763 A1
(43) Pub. Date: Mar. 20, 2025

(54) ENERGY HARVESTER ARRANGEMENT, METHOD AND SYSTEM

(71) Applicant: Baker Hughes Oilfield Operations LLC, Houston, TX (US)

(72) Inventors: Ronnie Russell, Cypress, TX (US); Kamalesh Chatterjee, Tomball, TX (US); Daniel Ewing, Katy, TX (US); Christopher Hern, Porter, TX (US); Andrew Duggan, Meadows Place, TX (US); Aaron C. Hammer, Houston, TX (US); Izhar Ahmad, Spring, TX (US); Stewart Blake Brazil, Edmond, OK (US)

(21) Appl. No.: 18/470,660

(22) Filed: Sep. 20, 2023

(51) Int. Cl. E21B 41/00

(52) U.S. Cl. CPC E21B 41/0085

(57) ABSTRACT

An energy harvester arrangement including a housing, a port in the housing, a first member whose position relative to the housing depends upon a Bernoulli effect on the member from a fluid flow through the port, and a piezoelectric voltage generator operably connected to the member. A method for generating electricity, comprising flowing a fluid past a member, the fluid creating pressure change dependent upon flow velocity, causing a movement of the member by the pressure change, physically deforming a piezoelectric generator with the movement, and generating a voltage with the deforming. A system including a structure having a flow path for a fluid, an energy harvesting arrangement, disposed within at least a portion of the flow path. A borehole system, including a borehole in a subsurface formation, a string in the borehole, and an arrangement disposed within or as a apart of the string.

### BACKGROUND

In the resource recovery and fluid sequestration industries, instrumented structures in the downhole environment continually become more prevalent. This comes with increasing demand for power. While conduits for power can be run, they occupy space that is already at a premium. Batteries can eliminate the conduits but have limited lifetimes. Alternate sources of power would be welcomed by the art.

### SUMMARY

An embodiment of an energy harvester arrangement including a housing, a port in the housing, a first member whose position relative to the housing depends upon a Bernoulli effect on the member from a fluid flow through the port, and a piezoelectric voltage generator operably connected to the member.

An embodiment of a method for generating electricity, comprising flowing a fluid past a member, the fluid creating pressure change dependent upon flow velocity, causing a movement of the member by the pressure change, physically deforming a piezoelectric generator with the movement, and generating a voltage with the deforming.

An embodiment of a system including a structure having a flow path for a fluid, an energy harvesting arrangement, disposed within at least a portion of the flow path.

An embodiment of a borehole system, including a borehole in a subsurface formation, a string in the borehole, and an arrangement disposed within or as a part of the string.

### BRIEF DESCRIPTION OF THE DRAWINGS

The following descriptions should not be considered limiting in any way. With reference to the accompanying drawings, like elements are numbered alike:

FIG. 1 is a view of an energy harvester arrangement as disclosed herein in an annular flow pathway;

FIG. 2 is an enlarged view of a portion of FIG. 1;

FIG. 3 is an enlarged view similar to FIG. 2 but substituting a spring for the cantilevered structure of FIG. 2;

FIG. 4 is the harvester arrangement of FIGS. 1 and 2 but with a different flow path;

FIG. 5 is an alternate embodiment of the FIG. 1 embodiment;

FIG. 6 is a view similar to that of FIG. 1 but having harvesters for flow in both directions through the arrangement;

FIG. 7 is an enlarged view of a portion of FIG. 6; and

FIG. 8 is a view of a borehole system including an energy harvester arrangement as disclosed herein.

### DETAILED DESCRIPTION

A detailed description of one or more embodiments of the disclosed apparatus and method are presented herein by way of exemplification and not limitation with reference to the Figures.

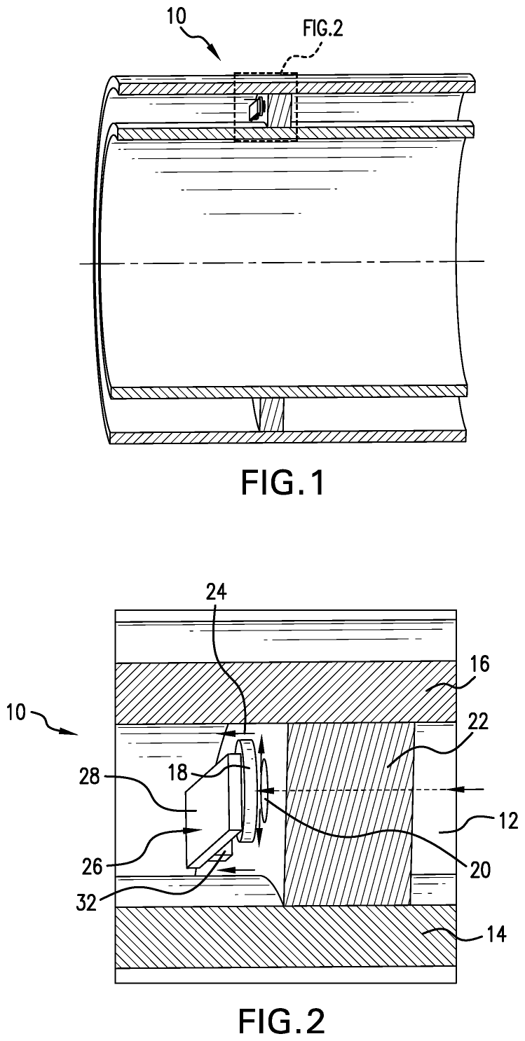

Referring to FIG. 1, an energy harvester arrangement 10 is illustrated. The arrangement 10 is disposed in an annular space 12 between an inner tube 14 and an outer tube 16. These tubes may be for example, nested tubular structures of a wellbore system or other structure that provides flow in the annular space 12. It may be, in some embodiments, that the annular space 12 is a part of an inflow conduit from a hydrocarbon bearing formation (which would be radially outwardly disposed of the outer tube 16). The arrangement 10 may in this instance also be an inflow control device such as a Lift inflow control device commercially available from Baker Hughes, Houston, Texas. One of skill in the art will recognize the similarity to the stated device and the distinctions that are disclosed herein.

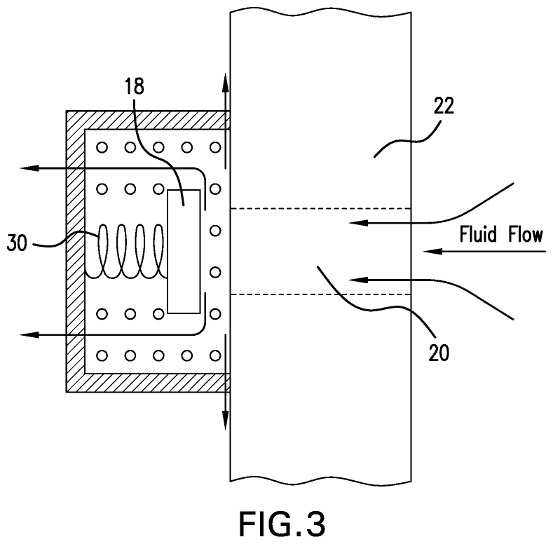

The harvester arrangement 10 takes advantage of a physical condition of the Lift inflow control device and other devices operating on a similar principal in that a disk 18 remains in motion while flow is active through a port 20 in a housing 22. Specifically, fluid flowing through the port 20 will flow around the disk 18 as illustrated by arrows 24 in FIG. 2. This flow regime causes low pressure due to a Bernoulli effect of the flossing fluid that is dependent upon the fluid velocity (which itself may be dependent upon the fluid viscosity). Along with changing fluid velocity, the low pressure areas change in pressure and pull the disk 18 toward those areas. Also, along with this changing velocity, the low pressure areas will get less different with reducing velocity and the disk 18 is pulled less energetically into the low pressure zones. The disk 18 itself also enhances the velocity change due to its own movement. Therefore, the disk 18 will essentially vibrate based upon both stated inputs (changing velocity and changing position affecting the velocity). The vibration of the disk 18 is captured in the arrangement 10 by a piezoelectric element 26. The element 26 may be a cantilevered structure 28 as illustrated in FIG. 2, may be a spring structure 30 as illustrated in FIG. 3, etc. The cantilevered structure 28 is affixed to the housing 22 through an affixation 32 such as a fastener, weld, adhesive, etc.

With the movement of the disk 18, the element 26 is deformed, whereby a voltage potential is generated. This energy may be collected and stored or used immediately to power electrical devices in the downhole environment.

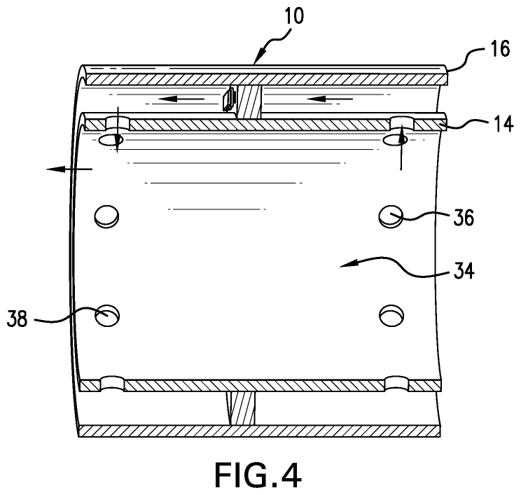

Referring to FIG. 4, an alternate embodiment is illustrated. The embodiment is substantially the same as the embodiment of FIG. 1 but provides for flow in the annular space 12 ancillarily to a primary flow in an inside diameter (ID) flow space 34 of the inner tubular 14. To this end, openings 36 are provided in the tubular 14 upstream of the arrangement 10 and openings 38 are provided in the tubular 14 downstream of the arrangement 10. Flow will naturally divert to the annulus 12 to some extent, and this may be enhanced to induce an increased power generation in arrangement 10 by restricting the flow in the flow space 34 by installing a flow restrictor such as a baffle, surface roughness, etc. between the openings 36 and 38.

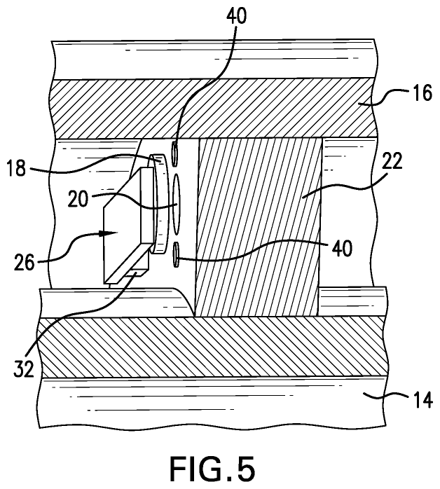

Referring to FIG. 5, stops 40 are illustrated. These are employable in each of the forgoing embodiments to prevent the arrangement 10 acting a check valve in conditions where flow has reversed. This might occur where chemicals are being injected into the formation or for any reason that results in a pressure differential opposite that contemplated for direction of flow above. Accordingly, 40, 18, 26 and 32 may be duplicated on the opposite side of port 20 to harvest energy in exactly the same way but with a reversed flow direction. Hence, the embodiment where stops 40 are used and the components just noted are duplicated on either side of housing 22 and port 20, will generate power with fluid flowing in either direction.

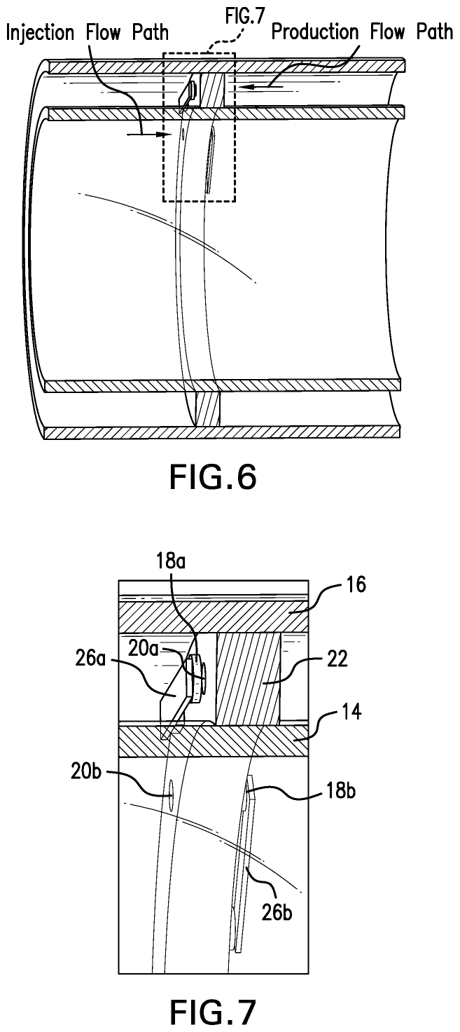

Referring to FIGS. 6 and 7, an alternate arrangement is illustrated for generating power in both directions of fluid flow through the arrangement 10. Alpha characters a and b are used in connection with this embodiment to indicate components that are the same but on different sides of the housing 22 so that they respond to different flow directions. In this embodiment, different ports 20a and 20b are employed each utilized for a dedicated flow direction. For port 20a, the components (18a, 26a), are identical to those illustrated in FIG. 2 and flow direction is to the left of the Figure. For port 20b, the components (18b, 26b) are the same but oriented oppositely to function in an opposite flow direction, i.e., with flow to the right of the Figure. In one iteration, the flow to the left is a production flow while the flow to the right is an injection flow, though the structure is not limited to these parameters.

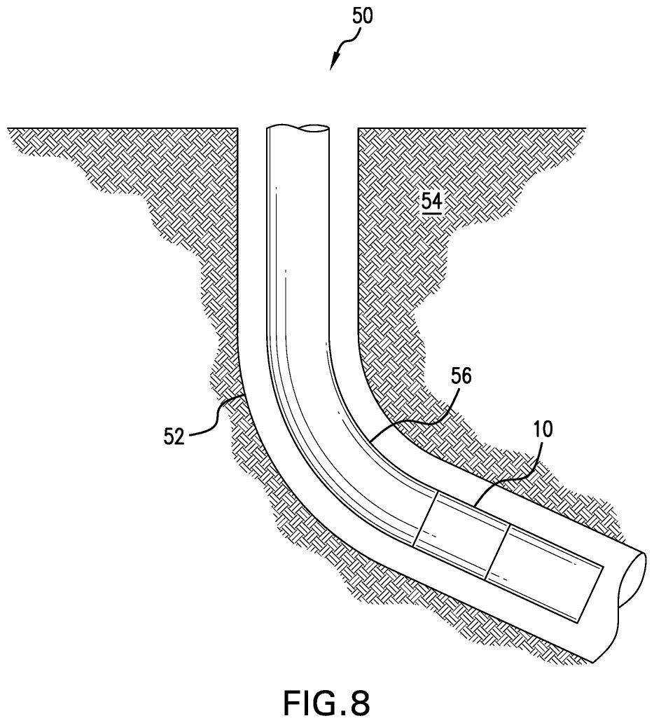

Referring to FIG. 8, a borehole system 50 is illustrated. The system 50 comprises a borehole 52 in a subsurface formation 54. A string 56 is disposed within the borehole 52. An energy harvester arrangement 10 as disclosed herein is disposed within or as a part of the string 56.

Set forth below are some embodiments of the foregoing disclosure:
Embodiment 1: An energy harvester arrangement including a housing, a port in the housing, a first member whose position relative to the housing depends upon a Bernoulli effect on the member from a fluid flow through the port, and a piezoelectric voltage generator operably connected to the member.
Embodiment 2: The arrangement as in any prior embodiment, wherein the Bernoulli effect of the flowing fluid causes the member to move cyclically, during use.
Embodiment 3: The arrangement as in any prior embodiment, wherein the first member is a disk.
Embodiment 4: The arrangement as in any prior embodiment, wherein the generator is a cantilevered structure.
Embodiment 5: The arrangement as in any prior embodiment, wherein the member is affixed to the generator.
Embodiment 6: The arrangement as in any prior embodiment, wherein the generator comprises a spring.
Embodiment 7: The arrangement as in any prior embodiment, wherein the member is drawn toward the housing with increasing fluid flow velocity.
Embodiment 8: The arrangement as in any prior embodiment, wherein the housing includes a stop that prevents the member from eliminating flow through the port.
Embodiment 9: The arrangement as in any prior embodiment, further including a second member disposed adjacent the port and on an opposing side of the housing from the first member whose position relative to the housing depends upon flow through the port.
Embodiment 10: The arrangement as in any prior embodiment, further including a second port in the housing, the second port being adjacent a second member, the second member position relative to the housing being dependent upon flow through the second port; and a second piezoelectric voltage generator operably connected to the second member.
Embodiment 11: The arrangement as in any prior embodiment, wherein the magnitude of the Bernoulli effect is based upon viscosity of the fluid flowing through the arrangement.
Embodiment 12: A method for generating electricity, comprising flowing a fluid past a member, the fluid creating pressure change dependent upon flow velocity, causing a movement of the member by the pressure change, physically deforming a piezoelectric generator with the movement, and generating a voltage with the deforming.
Embodiment 13: The method as in any prior embodiment, wherein the pressure change is by Bernoulli effect.
Embodiment 14: The method as in any prior embodiment, wherein the pressure change is a reduced pressure.
Embodiment 15: A system including a structure having a flow path for a fluid, an energy harvesting arrangement as in any prior embodiment, disposed within at least a portion of the flow path.
Embodiment 16: The system as in any prior embodiment, wherein the flow path is a diverted portion of another flow path.
Embodiment 17: The system as in any prior embodiment, wherein the structure is a tubular member of a wellbore system.
Embodiment 18: The system as in any prior embodiment, wherein the structure is an inflow control device.
Embodiment 19: A borehole system, including a borehole in a subsurface formation, a string in the borehole, and an arrangement as in any prior embodiment disposed within or as a part of the string.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% of a given value.

The teachings of the present disclosure may be used in a variety of well operations. These operations may involve using one or more treatment agents to treat a formation, the fluids resident in a formation, a borehole, and/or equipment in the borehole, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. An energy harvester arrangement comprising:
a housing;
a port in the housing;
a first member whose position relative to the housing depends upon a Bernoulli effect on the member from a fluid flow through the port; and
a piezoelectric voltage generator operably connected to the member.

2. The arrangement as claimed in claim 1, wherein the Bernoulli effect of the flowing fluid causes the member to move cyclically, during use.

3. The arrangement as claimed in claim 1, wherein the first member is a disk.

4. The arrangement as claimed in claim 1, wherein the generator is a cantilevered structure.

5. The arrangement as claimed in claim 4, wherein the member is affixed to the generator.

6. The arrangement as claimed in claim 1, wherein the generator comprises a spring.

7. The arrangement as claimed in claim 2, wherein the member is drawn toward the housing with increasing fluid flow velocity.

8. The arrangement as claimed in claim 1, wherein the housing includes a stop that prevents the member from eliminating flow through the port.

9. The arrangement as claimed in claim 1, further including a second member disposed adjacent the port and on an opposing side of the housing from the first member whose position relative to the housing depends upon flow through the port.

10. The arrangement as claimed in claim 1, further including a second port in the housing, the second port being adjacent a second member, the second member position relative to the housing being dependent upon flow through the second port; and
a second piezoelectric voltage generator operably connected to the second member.

11. The arrangement as claimed in claim 1, wherein the magnitude of the Bernoulli effect is based upon viscosity of the fluid flowing through the arrangement.

12. A method for generating electricity, comprising:
flowing a fluid past a member, the fluid creating pressure change dependent upon flow velocity;
causing a movement of the member by the pressure change;
physically deforming a piezoelectric generator with the movement; and
generating a voltage with the deforming.

13. The method as claimed in claim 12, wherein the pressure change is by Bernoulli effect.

14. The method as claimed in claim 12, wherein the pressure change is a reduced pressure.

15. A system comprising:
a structure having a flow path for a fluid;
an energy harvesting arrangement as claimed in claim 1, disposed within at least a portion of the flow path.

16. The system as claimed in claim 15 wherein the flow path is a diverted portion of another flow path.

17. The system as claimed in claim 15 wherein the structure is a tubular member of a wellbore system.

18. The system as claimed in claim 15 wherein the structure is an inflow control device.

19. A borehole system, comprising:
a borehole in a subsurface formation;
a string in the borehole; and
an arrangement as claimed in claim 1 disposed within or as a part of the string.
